(19) United States
(12) Patent Application Publication
(10) Pub. No.: US 2010/0200064 A1
(43) Pub. Date: Aug. 12, 2010

(54) DYE-SENSITIZING SOLAR CELL AND FABRICATING METHOD THEREOF

(75) Inventors: Chuan-Ya Hung, Hsinchu County (TW); Wen Hsiang Yen, Hsinchu City (TW); Sz-Ping Fu, Hsinchu County (TW); Yung-Liang Tung, Hualien County (TW); Song-Yeu Tsai, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/427,754

(22) Filed: Apr. 22, 2009

(30) Foreign Application Priority Data
Feb. 9, 2009 (TW) 98104033

(51) Int. Cl. H01L 31/0203; H01L 31/02; H01L 21/50

(52) U.S. Cl. 136/259; 438/64; 257/E31.11; 257/E21.499

(57) ABSTRACT

A dye-sensitizing solar cell (DSSC) is provided. The DSSC includes a working electrode, a counter electrode disposed opposite to the working electrode, a first gap control layer disposed between the working electrode and the counter electrode, a packaging material, and an electrolyte. The working electrode has a first patterned conductive line. The counter electrode has a second patterned conductive line. The first gap control layer is located on at least an outer portion of one of the first and the second patterned conductive lines to surround at least the first and the second patterned conductive lines or is symmetrically located on one of the first and the second patterned conductive lines. The packaging material is disposed on the first gap control layer such that the working electrode, the counter electrode, the first gap control layer, and the packaging material form a gap. The electrolyte is disposed in the gap.

### CROSS-REFERENCE TO RELATED APPLICATION

This application claims the priority benefit of Taiwan application serial no. 98104033, filed on Feb. 9, 2009. The entirety of the above-mentioned patent application is hereby incorporated by reference herein and made a part of this specification.

### BACKGROUND OF THE INVENTION

1. Field of the Invention

The present invention generally relates to a solar cell and a fabricating method thereof, and more particularly, to a dye-sensitizing solar cell (DSSC) and a fabricating method thereof.

2. Description of Related Art

Solar cell is a very promising and clean energy source which can convert solar energy directly into electricity. However, the production cost of solar cell has to be greatly reduced to allow solar cell to be broadly accepted as the major source of electricity. Dye-sensitizing solar cell (DSSC) is a solar cell which can effectively utilize solar energy. In addition, DSSC is easy to fabricate and has lower production cost. Accordingly, DSSC has become one of the most promising third-generation solar cells after silicon solar cell.

FIG. 1 is a cross-sectional view of a conventional DSSC. Referring to FIG. 1, the DSSC 10 includes transparent substrates 100 and 102, transparent conductive films 104 and 106, a titanium dioxide layer 108, a packaging material 110, an electrolyte 112, and conductive lines 116 and 118. The transparent substrates 100 and 102 are disposed opposite to each other. The transparent conductive film 104 and the titanium dioxide layer 108 are sequentially disposed on the transparent substrate 100 as a working electrode, and the titanium dioxide layer 108 carries a dye. The transparent conductive film 106 is disposed on the transparent substrate 102 as a counter electrode. The packaging material 110 is disposed between the transparent substrates 100 and 102 to form a gap 114 between the transparent substrates 100 and 102. The electrolyte 112 is disposed in the gap 114. The conductive lines 116 and 118 are respectively disposed on the transparent conductive films 104 and 106 for collecting currents.

In the packaging process of the DSSC 10, the packaging material 110 is first coated between the transparent substrates 100 and 102. Then, the transparent substrates 100 and 102 are pressed together. Next, the packaging material 110 is cured. However, if the transparent substrates 100 and 102 receive an uneven force when they are pressed together, the gap 114 may become uneven at different areas, and accordingly, the photoelectric conversion efficiency of the DSSC 10 may be reduced.

In addition, foregoing situation may also cause the transparent conductive films 104 and 106 to get into contact (as shown in FIG. 2A) or the conductive lines 116 and 118 to get into contact (as shown in FIG. 2B), and accordingly may cause the problem of short circuit.

### SUMMARY OF THE INVENTION

Accordingly, the present invention is directed to a dye-sensitizing solar cell (DSSC) having a high photoelectric conversion efficiency.

The present invention is also directed to a fabricating method of a DSSC which offers an improved production yield.

The present invention provides a DSSC including a working electrode, a counter electrode, a first gap control layer, a packaging material, and an electrolyte. The working electrode has a first patterned conductive line. The counter electrode is disposed opposite to the working electrode and has a second patterned conductive line. The first gap control layer is disposed between the working electrode and the counter electrode, and the first gap control layer is located on at least an outer portion of one of the first patterned conductive line and the second patterned conductive line to at least surround the first patterned conductive line and the second patterned conductive line or is symmetrically located on one of the first patterned conductive line and the second patterned conductive line. The packaging material is disposed on the first gap control layer such that a gap is constructed by the working electrode, the counter electrode, the first gap control layer, and the packaging material. The electrolyte is disposed in the gap.

The present invention also provides a fabricating method of a DSSC including following steps. First, a working electrode and a counter electrode disposed opposite to each other are provided, wherein the working electrode has a first patterned conductive line, and the counter electrode has a second patterned conductive line. Then, a first gap control layer is formed on at least an outer portion of one of the first patterned conductive line and the second patterned conductive line to at least surround the first patterned conductive line and the second patterned conductive line, or the first gap control layer is symmetrically formed on one of the first patterned conductive line and the second patterned conductive line. Next, a packaging material is formed on the first gap control layer. Thereafter, the working electrode and the counter electrode are pressed together to form a gap between the working electrode and the counter electrode. Next, the packaging material is cured. After that, an electrolyte is filled into the gap.

In the present invention, a gap control layer is disposed between a working electrode and a counter electrode such that during the packaging process of a DSSC, contact between the transparent conductive films or patterned conductive lines of the working electrode and the counter electrode can be prevented if the working electrode and the counter electrode are pressed together and receive an uneven force, and accordingly the problem of short circuit can be avoided and the production yield can be improved. Moreover, in the present invention, by disposing the gap control layer between the working electrode and the counter electrode, the gap between the working electrode and the counter electrode is made stable and even, and accordingly the photoelectric conversion efficiency of the DSSC is improved. Furthermore, in the present invention, the gap control layer is disposed on the patterned conductive lines so that the light utilization efficiency of the DSSC can be sustained and the patterned conductive lines are protected from the erosion of the electrolyte.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a conventional dye-sensitizing solar cell (DSSC).

FIG. 2A and FIG. 2B are cross-sectional views illustrating how short circuit is caused in a conventional DSSC.

FIG. 3A is a top view of a working electrode according to an embodiment of the present invention.

FIG. 3B is a top view of a counter electrode according to an embodiment of the present invention.

FIG. 3C is a cross-sectional view of a DSSC having the working electrode in FIG. 3A and the counter electrode in FIG. 3B.

FIG. 4A is a cross-sectional view of a DSSC according to another embodiment of the present invention.

FIG. 4B is a cross-sectional view of a DSSC according to yet another embodiment of the present invention.

FIG. 5A is a top view of a working electrode according still another embodiment of the present invention.

FIG. 5B is a top view of a counter electrode according to the still another embodiment of the present invention.

FIG. 5C is a cross-sectional view of a DSSC having the working electrode in FIG. 5A and the counter electrode in FIG. 5B.

FIG. 6 is a flowchart of a fabricating method of a DSSC according to an embodiment of the present invention.

FIG. 7 illustrates the relationship between a gap control layer and a packaging success rate according to an embodiment of the present invention.

FIG. 8A is a top view of a working electrode according to another embodiment of the present invention.

FIG. 8B is a top view of a working electrode according to yet another embodiment of the present invention.

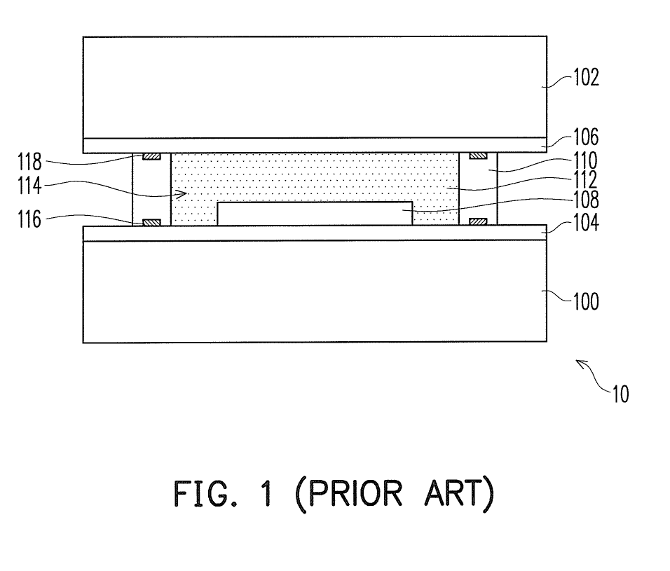

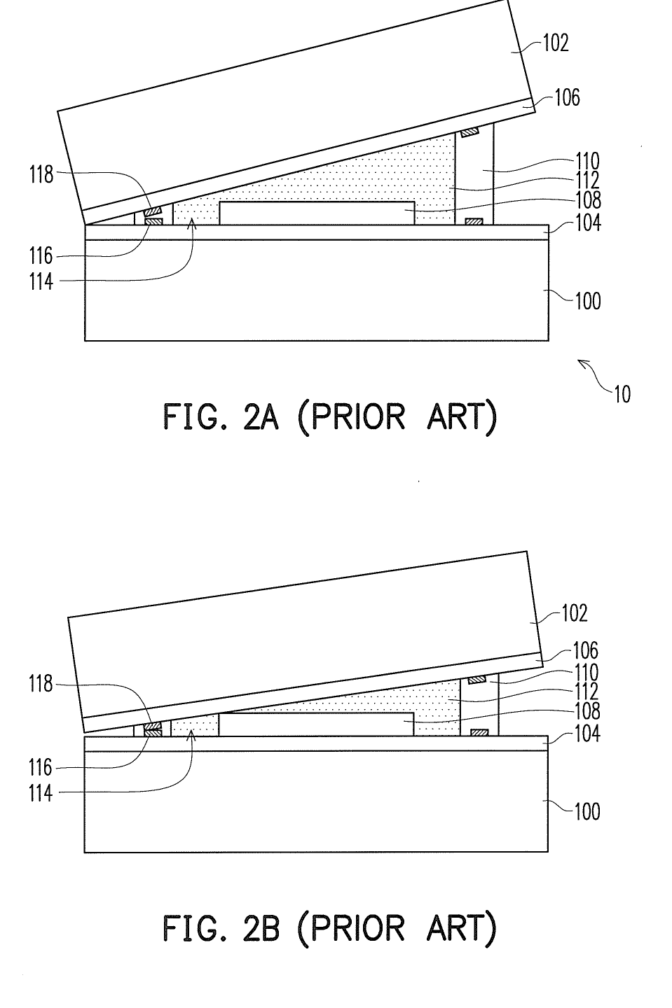

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

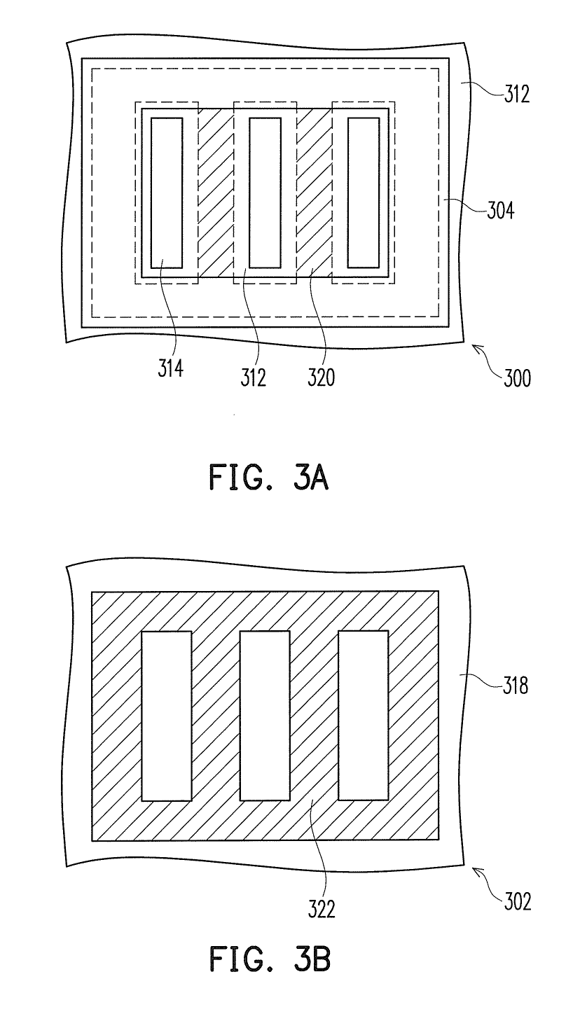

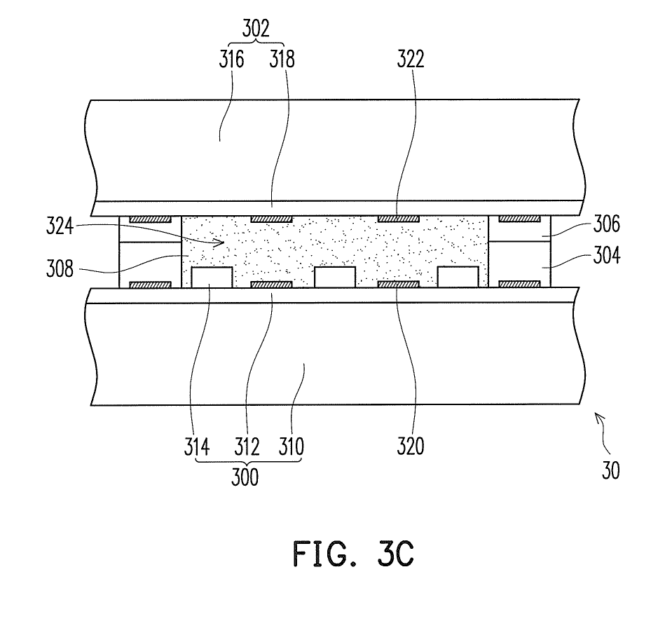

FIG. 3A is a top view of a working electrode according to an embodiment of the present invention. FIG. 3B is a top view of a counter electrode according to an embodiment of the present invention. FIG. 3C is a cross-sectional view of a dye-sensitizing solar cell (DSSC) having the working electrode in FIG. 3A and the counter electrode in FIG. 3B. Referring to FIGS. 3A˜3C, the DSSC 30 includes a working electrode 300, a counter electrode 302, a gap control layer 304, a packaging material 306, and an electrolyte 308. The working electrode 300 and the counter electrode 302 are disposed opposite to each other. The working electrode 300 includes a transparent substrate 310, a transparent conductive film 312, and a metal oxide layer 314, wherein the metal oxide layer 314 carries a dye. The transparent substrate 310 may be a glass substrate. The metal oxide layer 314 may be a titanium dioxide layer in nanometer level. The dye may be a Ru-complex dye. The counter electrode 302 includes a transparent substrate 316 and a transparent conductive film 318, wherein the transparent substrate 316 may be a glass substrate.

The working electrode 300 has a patterned conductive line 320, and the counter electrode 302 has a patterned conductive line 322. The material of the patterned conductive lines 320 and 322 may be silver. In the present embodiment, the patterned conductive line 320 and the patterned conductive line 322 have the same pattern, while in another embodiment of the present invention, the patterned conductive line 320 and the patterned conductive line 322 may have different patterns. The patterned conductive lines 320 and 322 are used for collecting currents therefore are electrically connected to an external circuit or device (not shown).

The gap control layer 304 is disposed between the working electrode 300 and the counter electrode 302 and located on an outer portion of the patterned conductive line 320 (i.e., the portion of the patterned conductive line 320 adjacent to the edge of the working electrode 300) to surround the patterned conductive line 320 and the patterned conductive line 322. The thickness of the gap control layer 304 may be between 5 μm and 100 μm. The material of the gap control layer 304 may be a glass frit, an adhesive, and a solvent. The glass frit may be one of B₂O₃, Na₂O, BaO, SnO, ZnO, P₂O₅, Bi₂O₃, SiO₂, and mixtures thereof, and which may turn into crystalline glass or non-crystalline glass after it is sintered. The adhesive is a material whose thermal decomposition temperature is lower than the glass transition temperature for 50° C. to 100° C., such as carboxy methyl cellulose sodium (CMC-Na), CMC, polyethylene glycols (PEG), ethyl cellulose, or acrylic. The solvent may be isopropyl alcohol, tert-butyl alcohol, ethylene glycol, ethyl digol, or terpineol. The packaging material 306 is disposed on the gap control layer 304 (i.e., between the gap control layer 304 and the transparent conductive film 318). The working electrode 300, the counter electrode 302, the gap control layer 304, and the packaging material 306 form a gap 324. The packaging material 306 may be glass, a UV curable material, or a thermoplastic material. To be specific, when the DSSC 30 is applied to a building material and accordingly needs to have a long life, the packaging material 306 should be glass. The glass adopted herein should be different from that adopted by the gap control layer 304, and the glass transition temperature thereof should be lower than that of the gap control glass for 50° C. When the DSSC 30 is applied to a consumable electronic product having a shorter product life cycle, the packaging material 306 should be a low-cost UV curable material or thermoplastic material. The UV curable material may be a polymer material containing acrylic and epoxy. The electrolyte 308 is disposed in the gap 324 for providing the redox reaction required by the DSSC 30. The electrolyte 308 may be a solution of iodine and triiodide.

It should be mentioned that the gap control layer 304 may have a coarse surface so that the adhesion between the gap control layer 304 and the packaging material 306 can be increased and accordingly the packaging mechanical strength of the DSSC 30 can be improved.

Because the gap control layer 304 is disposed between the working electrode 300 and the counter electrode 302, the distance between the working electrode 300 and the counter electrode 302 can be controlled by adjusting the thickness of the gap control layer 304 according to the actual requirement. Besides, during the packaging process of the DSSC 30, the gap control layer 304 can prevent the gap 324 from becoming uneven if an uneven force is received by the working electrode 300 and the counter electrode 302 when they are pressed together, and accordingly can prevent the transparent conductive films 312 and 318 from contacting each other or the patterned conductive lines 320 and 322 from contacting each other. As a result, the problem of short circuit can be avoided and the packaging yield can be improved. In addition, because the gap control layer 304 can prevent the gap 324 from being uneven at different areas, the photoelectric conversion efficiency of the DSSC 30 can be improved. Moreover, the light utilization efficiency of the DSSC 30 can be sustained by disposing the gap control layer 304 on the patterned conductive line 320.

In the embodiment described above, the gap control layer 304 is only located on the outer portion of the patterned conductive line 320. In another embodiment of the present invention, the gap control layer may be disposed only on an outer portion of the patterned conductive line 322, or the gap control layer may also be respectively disposed on the outer portion of the patterned conductive line 320 and the outer portion of the patterned conductive line 322.

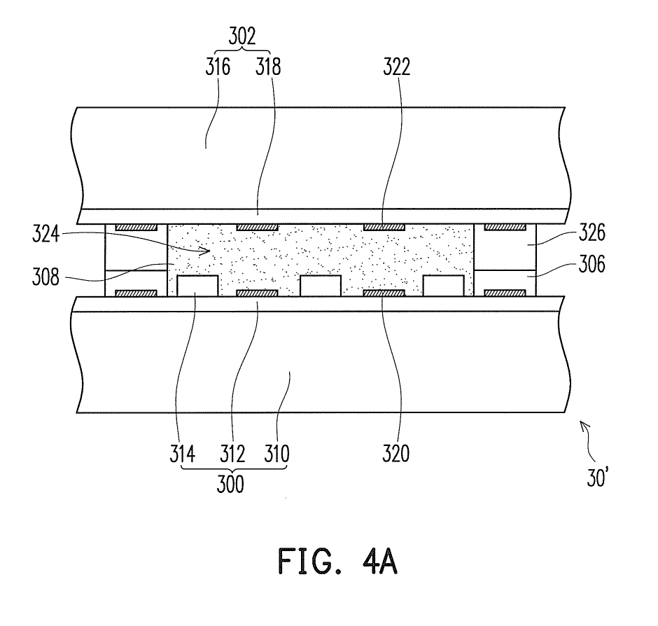

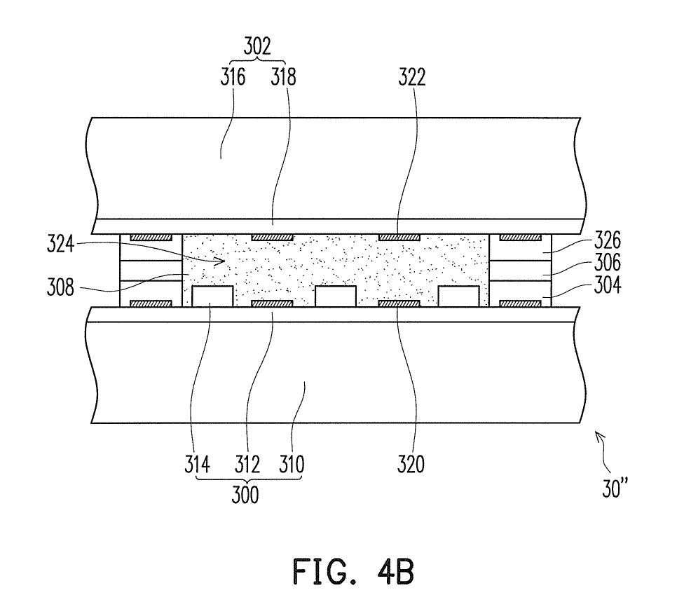

FIG. 4A is a cross-sectional view of a DSSC according to another embodiment of the present invention. Referring to FIG. 4A, in the DSSC 30′, the gap control layer 326 is disposed on an outer portion of the patterned conductive line 322, and the packaging material 306 is disposed on the gap control layer 326 (i.e., between the gap control layer 326 and the transparent conductive film 312). The thickness of the gap control layer 326 may be between 5 μm and 100 μm, and the material thereof may be similar to that of the gap control layer 304 therefore will not be described herein.

FIG. 4B is a cross-sectional view of a DSSC according to yet another embodiment of the present invention. Referring to FIG. 4B, in the DSSC 30″, the gap control layer 304 is disposed on an outer portion of the patterned conductive line 320, the gap control layer 326 is disposed on an outer portion of the patterned conductive line 322, and the packaging material 306 is disposed between the gap control layers 304 and 326.

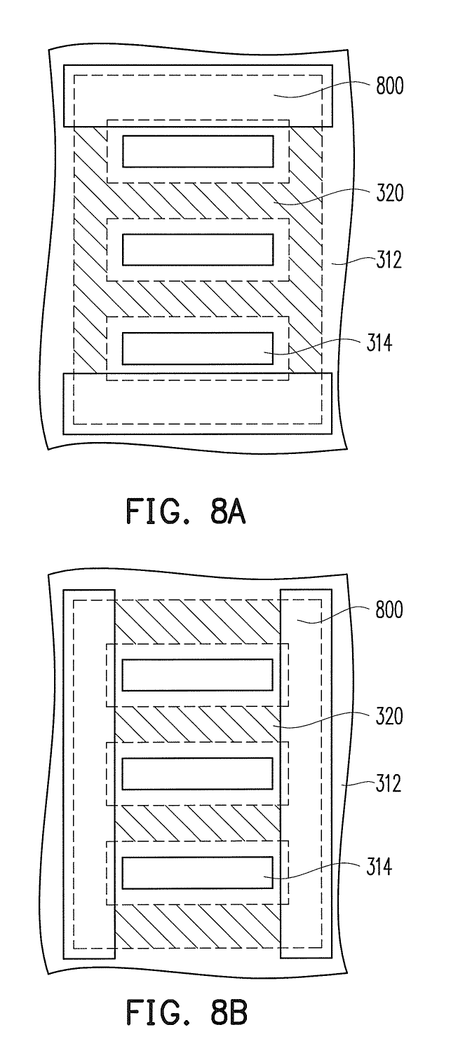

In the embodiment described above, the gap control layer is only disposed on an outer portion of a patterned conductive line. In another embodiment of the present invention, the gap control layer may also be symmetrically disposed on the patterned conductive line. As shown in FIG. 8A and FIG. 8B, the gap control layer 800 is symmetrically disposed on the patterned conductive line 320. However, in another embodiment of the present invention, the gap control layer 800 may also be symmetrically disposed on the patterned conductive line 322. Similarly, in yet another embodiment of the present invention, the gap control layers may also be symmetrically disposed on respectively the patterned conductive line 320 and the patterned conductive line 322.

Or, in some other embodiments of the present invention, the gap control layer may also be disposed on the entire patterned conductive line.

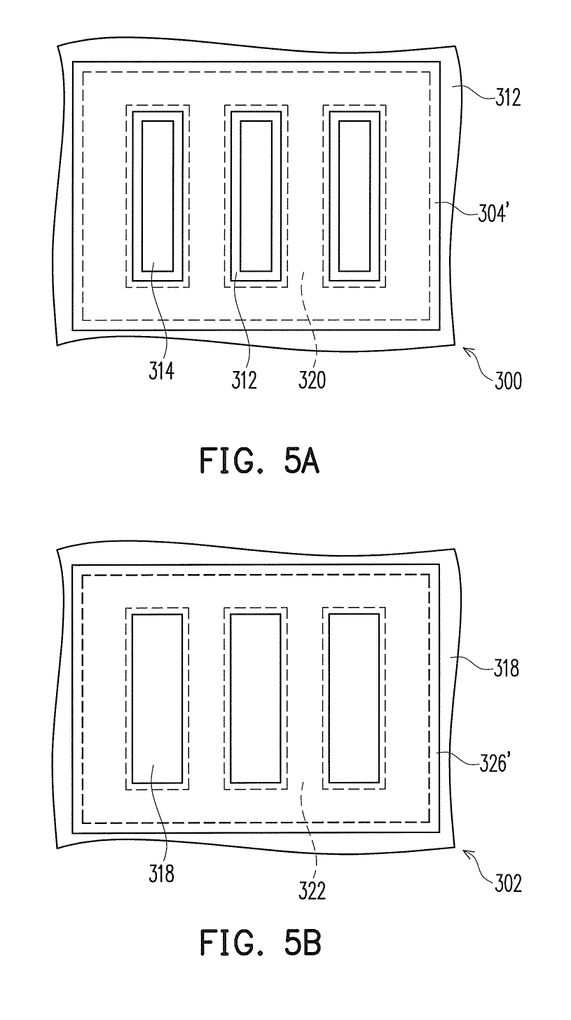

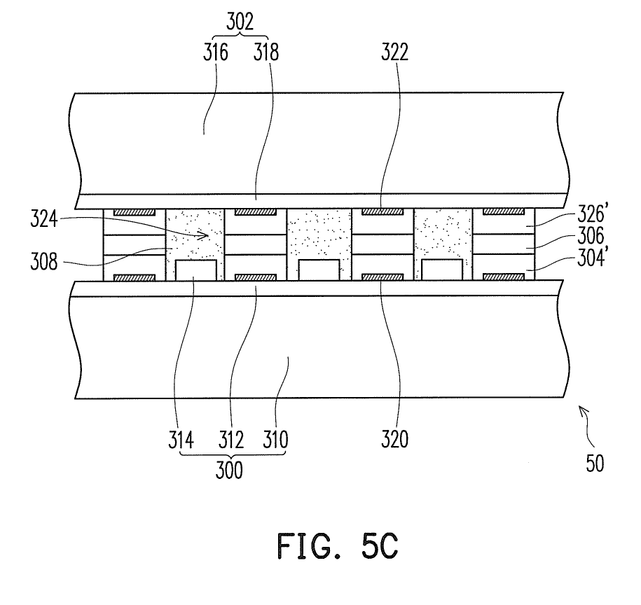

FIG. 5A is a top view of a working electrode according still another embodiment of the present invention. FIG. 5B is a top view of a counter electrode according to the still another embodiment of the present invention. FIG. 5C is a cross-sectional view of a DSSC having the working electrode in FIG. 5A and the counter electrode in FIG. 5B. Referring to FIGS. 5A˜5C, in the DSSC 50, the working electrode 300 has a patterned conductive line 320, and the counter electrode 302 has a patterned conductive line 322. The gap control layer 304′ is disposed on the entire patterned conductive line 320, the gap control layer 326′ is disposed on the entire patterned conductive line 322, and the packaging material 306 is disposed between the gap control layers 304′ and 326′. The thicknesses and materials of the gap control layers 304′ and 326′ are similar to those of the gap control layers 304 and 326 therefore will not be described herein. It should be mentioned that because the gap control layers 304′ and 326′ are respectively disposed on the entire patterned conductive line 320 and the entire patterned conductive line 322, the patterned conductive line 320 and the patterned conductive line 322 are prevented from contacting the electrolyte 308 so that the patterned conductive line 320 and the patterned conductive line 322 are protected from the erosion of the electrolyte 308.

A DSSC fabricating method provided by the present invention will be described below with the DSSC 50 in FIG. 5C as an example.

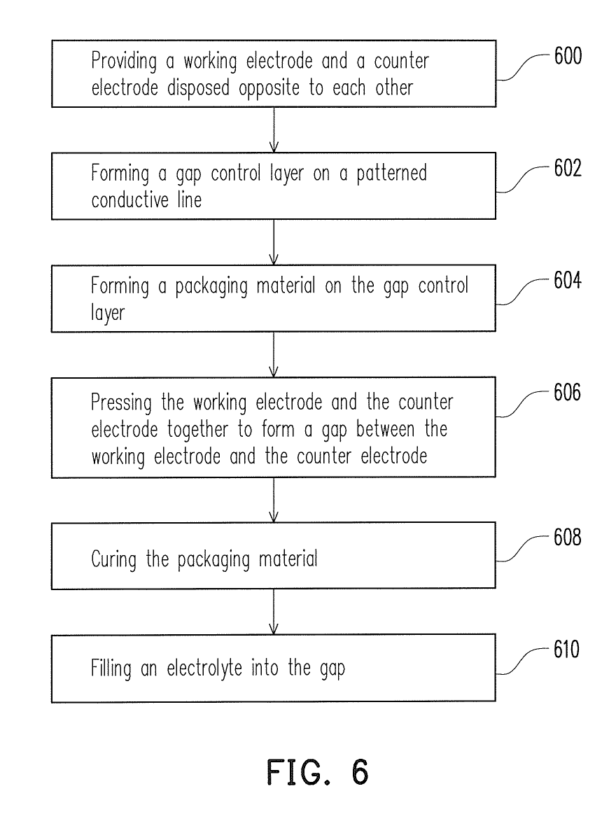

FIG. 6 is a flowchart of a fabricating method of a DSSC according to an embodiment of the present invention. Referring to FIGS. 5A˜5C and FIG. 6, first, in step 600, a working electrode 300 and a counter electrode 302 disposed opposite to each other are provided, wherein the working electrode 300 has a patterned conductive line 320, and the counter electrode 302 has a patterned conductive line 322.

Then, in step 602, a gap control layer 304′ and a gap control layer 326′ are respectively formed on the patterned conductive line 320 and the patterned conductive line 322. The gap control layer 304′ may be formed by printing a gap control material on the patterned conductive line 320 first through screen printing and then co-firing the gap control material and the metal oxide layer 314 to solidify the gap control material. The gap control material may be prepared by mixing a glass frit, an adhesive, and a solvent together and ball milling the mixture with a milling ball for 24 hours. The thickness of the gap control layer 304′ can be adjusted according to the solid content of the gap control material and printing process parameters, so as to stabilize and uniform the thickness of the gap control layer 304′. The printing process parameters include screen emulsion thickness, mesh size, and printing speed. The gap control layer 326′ is formed through the same method as the gap control layer 304′ therefore will not be described again.

It should be mentioned that after the gap control layers are formed, a sand-blasting process may be further performed to the surfaces of the gap control layers to increase the adhesion between the gap control layers and a packaging material formed subsequently and accordingly to improve the packaging mechanical strength of the DSSC.

Next, in step 604, a packaging material 306 is formed on the gap control layer 304′ or the gap control layer 326′, or the packaging material 306 is formed on both the gap control layers 304′ and 326′. The packaging material 306 may be formed through screen printing.

Thereafter, in step 606, the working electrode 300 and the counter electrode 302 are pressed together to form a gap 324 between the working electrode 300 and the counter electrode 302. After that, in step 608, the packaging material 306 is cured. To be specific, if the packaging material 306 is glass, after the packaging material 306 is formed, the working electrode 300 and the counter electrode 302 are first aligned and then thermal pressed with a vacuum thermal pressing machine, wherein the pressure may be 500 mbar, the temperature may be between 440° C. and 470° C., and the pressing time may be between 20 minutes and 40 minutes. Besides, if the packaging material 306 is a UV curable material, the packaging material 306 is first coated on the gap control layer with a glue dispenser. Then, the working electrode 300 and the counter electrode 302 are aligned. Thereafter, the packaging material 306 is cured with a UV beam. In addition, if the packaging material 306 is a thermoplastic material, the thermoplastic material is first placed on the gap control layer. Then, a pressure between 1.5 MPa and 2 MPa is supplied, and the thermoplastic material and the gap control layer are heated to a temperature between 100° C. and 150° C.

Thereafter, in step 610, the electrolyte 308 is filled into the gap 324 to complete the fabrication of the DSSC 50.

Besides for fabricating the DSSC 50, the fabricating method described above may also be used for fabricating DSSCs in other embodiments of the present invention, and the fabricating steps are similar to those illustrated in FIG. 6 therefore will not be described herein.

Additionally, in the embodiment described above, the metal oxide layer in the working electrode is formed on the transparent conductive film before the patterned conductive line and the gap control material are formed. In another embodiment of the present invention, the metal oxide layer may also be formed according to the actual requirement after the patterned conductive line and the gap control material are formed.

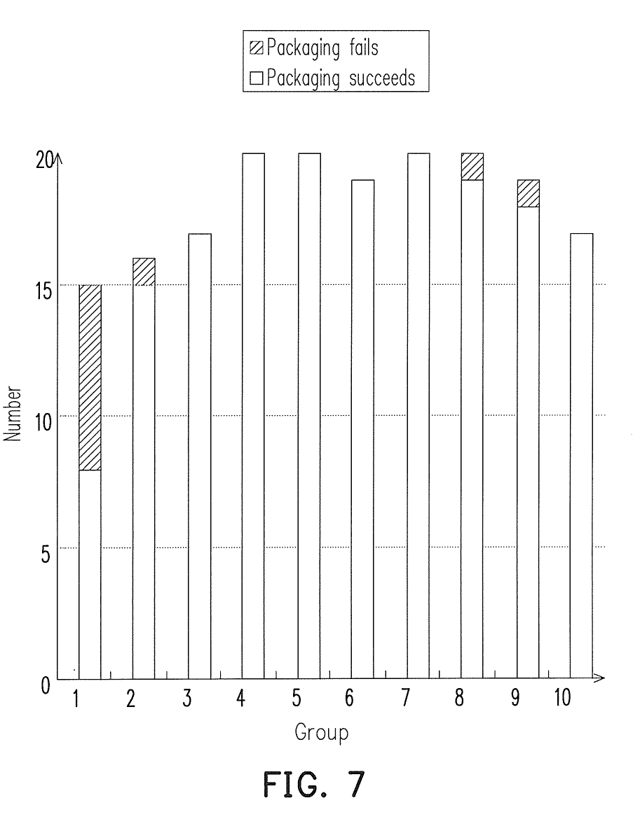

Below, the relationship between whether or not a gap control layer is disposed between the working electrode and the counter electrode and the packaging success rate will be described below with reference to FIG. 7.

FIG. 7 illustrates the relationship between a gap control layer and a packaging success rate according to an embodiment of the present invention. Referring to FIG. 7, the first group of DSSCs is packaged by not disposing a gap control layer between the working electrode and the counter electrode, and the second to the tenth group of DSSCs are packaged by disposing a gap control layer between the working electrode and the counter electrode. As shown in FIG. 7, the packaging success rate is 53% when the gap control layer is not disposed between the working electrode and the counter electrode (the first group), and the packaging success rate is between 95% and 100% when the gap control layer is disposed between the working electrode and the counter electrode (the second to the tenth group). Obviously, the packaging success rate is effectively increased by disposing a gap control layer between the working electrode and the counter electrode.

As described above, in the present invention, a gap control layer is disposed between a working electrode and a counter electrode. Thus, in the packaging process of a DSSC, the transparent conductive films or patterned conductive lines of the working electrode and the counter electrode can be prevented from getting into contact if an uneven force is received by the working electrode and the counter electrode when they are being pressed together. Accordingly, the problem of short circuit is avoided and the packaging yield is improved.

Moreover, in the present invention, the gap control layer is disposed between the working electrode and the counter electrode so that the gap between the working electrode and the counter electrode is made stable and even and accordingly the photoelectric conversion efficiency of the DSSC is improved.

Furthermore, in the present invention, a gap control layer is disposed on a patterned conductive line such that the light utilization efficiency of the DSSC can be sustained and the patterned conductive line can be protected from the erosion of the electrolyte.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A dye-sensitizing solar cell (DSSC), comprising:
a working electrode, having a first patterned conductive line;
a counter electrode, disposed opposite to the working electrode, having a second patterned conductive line;
a first gap control layer, disposed between the working electrode and the counter electrode, and located on at least an outer portion of one of the first patterned conductive line and the second patterned conductive line to at least surround the first patterned conductive line and the second patterned conductive line, or symmetrically located on one of the first patterned conductive line and the second patterned conductive line;
a packaging material, disposed on the first gap control layer such that a gap is constructed by the working electrode, the counter electrode, the first gap control layer, and the packaging material; and
an electrolyte, disposed in the gap.

2. The DSSC according to claim 1, wherein a thickness of the first gap control layer is between 5 μm and 100 μm.

3. The DSSC according to claim 1, wherein a material of the first gap control layer comprises a glass frit, an adhesive, and a solvent.

4. The DSSC according to claim 3, wherein the glass frit is one of B₂O₃, Na₂O, BaO, SnO, ZnO, P₂O₅, Bi₂O₃, SiO₂, and mixtures thereof.

5. The DSSC according to claim 3, wherein the adhesive comprises carboxy methyl cellulose sodium (CMC-Na), CMC, polyethylene glycols (PEG), ethyl cellulose, or acrylic.

6. The DSSC according to claim 3, wherein the solvent comprises isopropyl alcohol, tert-butyl alcohol, ethylene glycol, ethyl digol, or terpineol.

7. The DSSC according to claim 1, wherein the first gap control layer has a coarse surface.

8. The DSSC according to claim 1 further comprising a second gap control layer, wherein the second gap control layer is disposed on at least an outer portion of the other one of the first patterned conductive line and the second patterned conductive line to at least surround the first patterned conductive line and the second patterned conductive line or is symmetrically located on the other one of the first patterned conductive line and the second patterned conductive line, and the packaging material is located between the first gap control layer and the second gap control layer.

9. The DSSC according to claim 8, wherein a thickness of the second gap control layer is between 5 μm and 100 μm.

10. The DSSC according to claim 8, wherein a material of the second gap control layer comprises a glass frit, an adhesive, and a solvent.

11. The DSSC according to claim 10, wherein the glass frit is one of B₂O₃, Na₂O, BaO, SnO, ZnO, P₂O₅, Bi₂O₃, SiO₂, and mixtures thereof.

12. The DSSC according to claim 10, wherein the adhesive comprises CMC-Na, CMC, PEG, ethyl cellulose, or acrylic.

13. The DSSC according to claim 10, wherein the solvent comprises isopropyl alcohol, tert-butyl alcohol, ethylene glycol, ethyl digol, or terpineol.

14. The DSSC according to claim 8, wherein the second gap control layer has a coarse surface.

15. The DSSC according to claim 1, wherein the packaging material comprises glass, a UV curable material, or a thermoplastic material.

16. A fabricating method of a DSSC, comprising:
providing a working electrode and a counter electrode disposed opposite to each other, wherein the working electrode has a first patterned conductive line, and the counter electrode has a second patterned conductive line;
forming a first gap control layer on at least an outer portion of one of the first patterned conductive line and the second patterned conductive line to at least surround the first patterned conductive line and the second patterned conductive line, or symmetrically forming the first gap control layer on one of the first patterned conductive line and the second patterned conductive line;
forming a packaging material on the first gap control layer;
pressing the working electrode and the counter electrode to form a gap between the working electrode and the counter electrode;
curing the packaging material; and
filling an electrolyte into the gap.

17. The fabricating method according to claim 16, wherein a thickness of the first gap control layer is between 5 μm and 100 μm.

18. The fabricating method according to claim 16, wherein a material of the first gap control layer comprises a glass frit, an adhesive, and a solvent.

19. The fabricating method according to claim 18, wherein the glass frit is one of B₂O₃, Na₂O, BaO, SnO, ZnO, P₂O₅, Bi₂O₃, SiO₂, and mixtures thereof.

20. The fabricating method according to claim 18, wherein the adhesive comprises CMC-Na, CMC, PEG, ethyl cellulose, or acrylic.

21. The fabricating method according to claim 18, wherein the solvent comprises isopropyl alcohol, tert-butyl alcohol, ethylene glycol, ethyl digol, or terpineol.

22. The fabricating method according to claim 16, wherein a method for forming the first gap control layer comprises:
printing a gap control material on one of the first patterned conductive line and the second patterned conductive line; and
solidifying the gap control material.

23. The fabricating method according to claim 16, wherein a method for forming the packaging material comprises a screen printing method.

24. The fabricating method according to claim 16, wherein after forming the first gap control layer and before forming the packaging material, the fabricating method further comprises performing a sand-blasting process to a surface of the first gap control layer.

25. The fabricating method according to claim 16 further comprising forming a second gap control layer on at least an outer portion of the other one of the first patterned conductive line and the second patterned conductive line to at least surround the first patterned conductive line and the second patterned conductive line, or symmetrically forming the second gap control layer on the other one of the first patterned conductive line and the second patterned conductive line.

26. The fabricating method according to claim 25, wherein a thickness of the second gap control layer is between 5 μm and 100 μm.

27. The fabricating method according to claim 25, wherein a material of the second gap control layer comprises a glass frit, an adhesive, and a solvent.

28. The fabricating method according to claim 27, wherein the glass frit is one of B₂O₃, Na₂O, BaO, SnO, ZnO, P₂O₅, Bi₂O₃, SiO₂, and mixtures thereof.

29. The fabricating method according to claim 27, wherein the adhesive comprises CMC-Na, CMC, PEG, ethyl cellulose, or acrylic.

30. The fabricating method according to claim 27, wherein the solvent comprises isopropyl alcohol, tert-butyl alcohol, ethylene glycol, ethyl digol, or terpineol.

31. The fabricating method according to claim 25, wherein after forming the second gap control layer and before pressing the working electrode and the counter electrode, the fabricating method further comprises performing a sand-blasting process to a surface of the second gap control layer.
